(19) United States
(12) Patent Application Publication
(10) Pub. No.: US 2021/0071965 A1
(43) Pub. Date: Mar. 11, 2021

(54) HEAT SINK HAVING PRESS-RIVETING STRUCTURE

(71) Applicant: Huizhou Hanxu Hardware & Plastic Technology Co., Ltd., Guangdong (CN)

(72) Inventor: Tsung-Hsien Huang, Guangdong (CN)

(21) Appl. No.: 16/565,493

(22) Filed: Sep. 10, 2019

(51) Int. Cl. F28F 3/06; H01L 23/367; B23P 15/26

(52) U.S. Cl. CPC F28F 3/06; F28D 2021/0029; B23P 15/26; H01L 23/3672

(57) ABSTRACT

A heat sink having a press-riveting structure includes a base and a heat sink fin. The heat sink fin is formed with a connecting portion, and the connecting portion is in contact with a contact surface of the base. One side of the heat sink fin can be stably supported, and it is easy for a press head to thrust a folded insertion portion of the heat sink fin, so that the heat sink fin is combined with the base more reliably, and the height of the heat sink fin is reduced. The heat sink fin won't be bent and deformed easily.

### BACKGROUND OF THE INVENTION

### 1. Field of the Invention

The present invention relates to a heat sink, and more particularly to a heat sink having a press-riveting structure.

### 2. Description of the Prior Art

The heat sink fins and the base of a conventional heat sink are assembled together by soldering or by pressing. The heat sink fins are first inserted in preset grooves or clamping seat, and then pressed by a press head so that the heat sink fins are clamped and combined with the grooves (or the clamping seat) of the base. For example, as disclosed in U.S. Pat. No. 5,014,776, the respective two side walls of the grooves are pressed to cause a deformation to clamp the heat sink fins, such that the heat sink fins and the base are assembled together.

In the above patent, through the deformation of both sides of the groove, the foot of the heat sink fin is clamped. However, the clamping force is concentrated at the deformation positions on both sides of the opening of the groove, only having two point-like clamping forces. Therefore, the clamping effect is not good and it is not easy to ensure its stable connection. The heat sink fins may have different heights, and the heat sink fins are prone to shaking or falling.

Another heat sink fin is formed with a folded portion by directly bending the end of the heat sink fin. The folded portion is pressed by a press head, so that the heat sink fin is combined with the base. For example, Chinese Utility Model Application No. 201820031179.0 discloses a double-sided inflated plate and a riveting structure of the double-sided inflated plate. The double-sided inflated plate is equivalent to a heat sink fin. The double-sided inflated plate has a neck. However, the neck is suspended, and the purpose of this design is to avoid the inflated structure of the double-sided inflated plate from blocking the press-riveting position. With the riveting structure, the double-sided inflated plate cannot be attached to the base firmly, and the double-sided inflated plate is easily bent and deformed. Besides, the contact area between the double-sided inflated plate and the base cannot be larger to improve heat dissipation efficiency. Accordingly, the inventor of the present invention has devoted himself based on his many years of practical experiences to solve these problems.

### SUMMARY OF THE INVENTION

In view of the shortcomings of the prior art, the primary object of the present invention is to provide a heat sink having a press-riveting structure, which can effectively solve the problem that the existing heat sink fins are not stable, easy to tilt, and have low heat dissipation efficiency.

In order to achieve the above object, the present invention adopts the following technical solutions:

A heat sink having a press-riveting structure comprises a base and a heat sink fin. A surface of the base is formed with a groove for attachment of the heat sink fin. At least one side of an opening of the groove has a contact surface. The heat sink fin includes an insertion portion, a connecting portion and a main body portion that are connected together. The insertion portion is a folded structure embedded in the groove. The connecting portion extends toward one side relative to the insertion portion and is at least partially in contact with the contact surface.

After the insertion portion of the heat sink fin is inserted in the groove of the base, a press head is aligned with the insertion portion for pressing, the press head covers the insertion portion, after pressing, the insertion portion is pressed down in the groove to be deformed, expanded and fitted in the groove tightly, such that the heat sink fin is combined with the base, and the connecting portion is in contact with the contact surface.

Compared with the prior art, the present invention has obvious advantages and beneficial effects. Specifically, it can be known from the above technical solutions:

The heat sink fin is formed with the connecting portion, and the connecting portion is in contact with the contact surface of the base. On the one hand, one side of the heat sink fin can be stably supported, and it is easy for the press head to thrust the folded insertion portion so that the heat sink fin is combined with the base more reliably, and the height of the heat sink fin is reduced. The heat sink fin won't be bent and deformed easily, and there is no skew phenomenon, ensuring that the heat dissipation passage formed between two heat sink fins is straight. On the other hand, the heat on the base can be directly transferred to the connecting portion, which effectively improves the heat dissipation efficiency.

### BRIEF DESCRIPTION OF THE DRAWINGS

FIG. 1 is a perspective view in accordance with a first embodiment of the present invention;

FIG. 2 is an enlarged view of the heat sink fin in accordance with the first embodiment of the present invention;

FIG. 3 is a front view in accordance with the first embodiment of the present invention;

FIG. 4 is a partial cross-sectional view showing the first state of the press-riveting process in accordance with the first embodiment of the present invention;

FIG. 5 is a partial cross-sectional view showing the second state of the press-riveting process in accordance with the first embodiment of the present invention;

FIG. 6 is a partial cross-sectional view showing the third state of the press-riveting process in accordance with the first embodiment of the present invention;

FIG. 7 is a perspective view in accordance with a second embodiment of the present invention;

FIG. 8 is a cross-sectional view in accordance with the second embodiment of the present invention;

FIG. 9 is a perspective view in accordance with a third embodiment of the present invention;

FIG. 10 is an enlarged view of the heat sink fin in accordance with the third embodiment of the present invention;

FIG. 11 is a front view in accordance with the third embodiment of the present invention;

FIG. 12 is a partial cross-sectional view showing the first state of the press-riveting process in accordance with the third embodiment of the present invention;

FIG. 13 is a partial cross-sectional view showing the second state of the press-riveting process in accordance with the third embodiment of the present invention;

FIG. 14 is a partial cross-sectional view showing the third state of the press-riveting process in accordance with the third embodiment of the present invention;

FIG. 15 is a perspective view in accordance with a fourth embodiment of the present invention; and

FIG. 16 is a cross-sectional view in accordance with the fourth embodiment of the present invention.

### DETAILED DESCRIPTION OF THE PREFERRED EMBODIMENTS

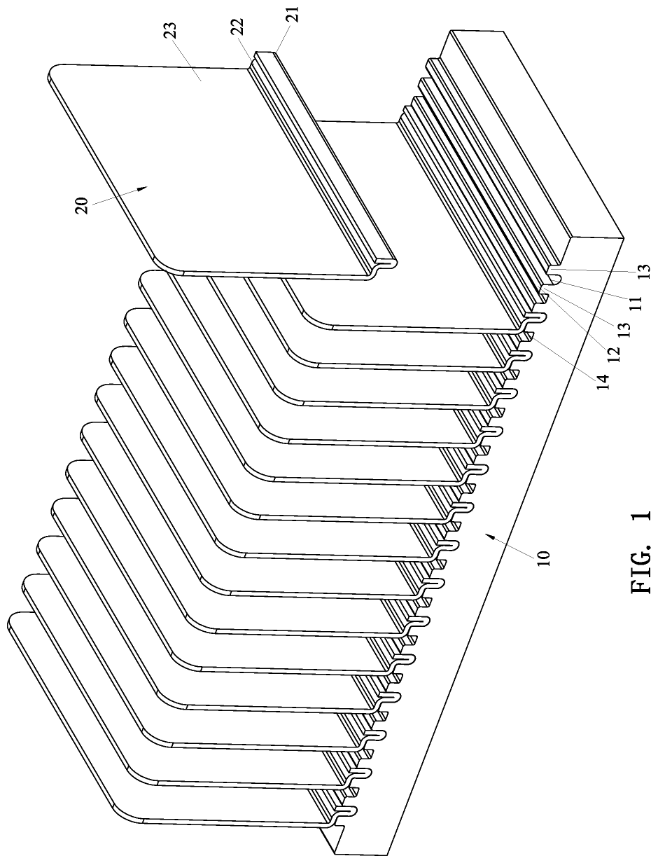

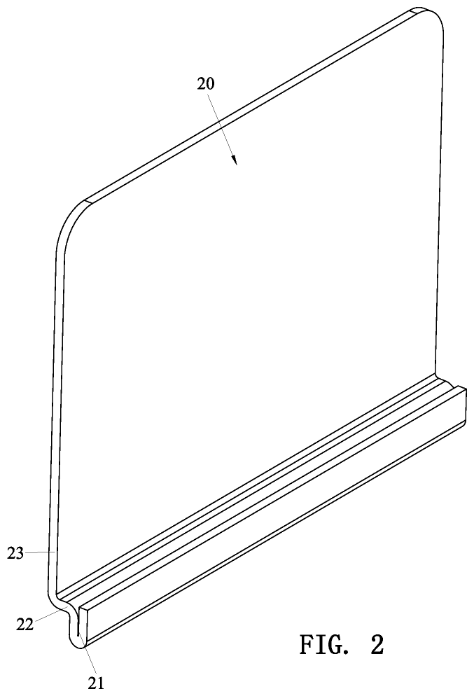

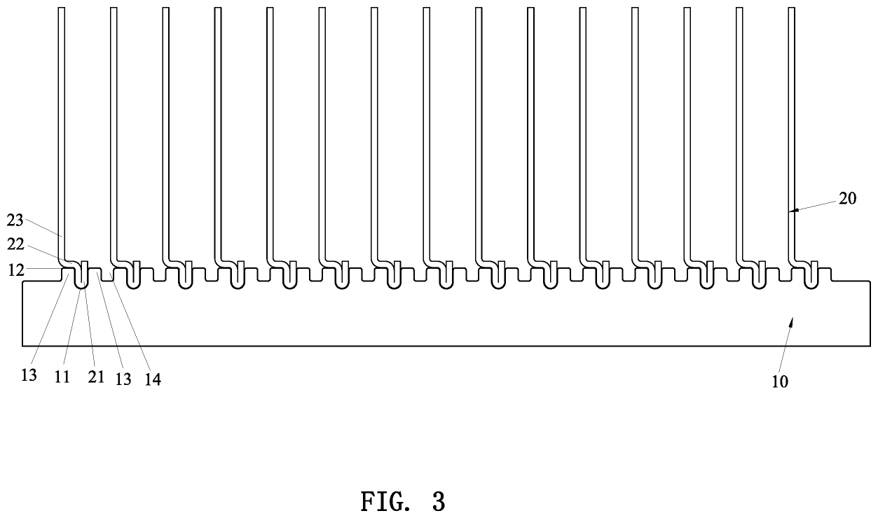

Referring to FIG. 1 through FIG. 6, a specific structure in accordance with a first embodiment of the present invention is shown, comprising a base 10 and a heat sink fin 20.

The surface of the base 10 is formed with a groove 11 for attachment of the heat sink fin 20. At least one side of the opening of the groove 11 has a contact surface 12. In this embodiment, the base 10 is made of copper, aluminum, copper-based alloy or aluminum-based alloy. A strip-shaped platform 13 is formed at either side of the groove 11. The contact surface 12 is located on the top surface of the strip-shaped platform 13. The contact surface 12 is a level surface, but not limited thereto, and may be a slope. The groove 11 is plural and arranged in parallel at intervals. The surface of the base 10 is recessed to form a concave groove 14 between every adjacent two of the grooves 11 to increase the heat dissipation area and improve the ventilation and heat dissipation effects.

The heat sink fin 20 includes an insertion portion 21, a connecting portion 22 and a main body portion 23 that are connected together. The insertion portion 21 is a folded structure and is embedded in the groove 11. The connecting portion 22 extends toward one side relative to the insertion portion 21 and is at least partially in contact with the contact surface 12. In this embodiment, the heat sink fin 20 is plural. The insertion portion 21 of each heat sink fin 20 is embedded and fixed in the corresponding groove 11. The insertion portion 21 is a U-shaped structure that is formed by folding one time. The underside of the connecting portion 22 is parallel to the contact surface 12 and is in full contact with the contact surface 12 to support the heat sink fin 20 better. The insertion portion 21, the connecting portion 22 and the main body portion 23 are integrally formed and connected from bottom to top. Both the insertion portion 21 and the main body portion 23 extend vertically. The connecting portion 22 extends horizontally.

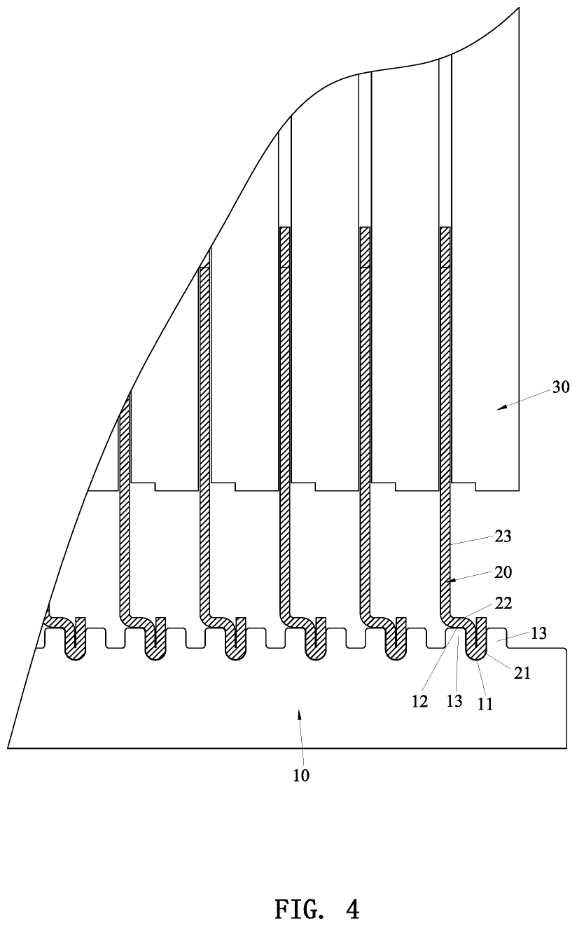

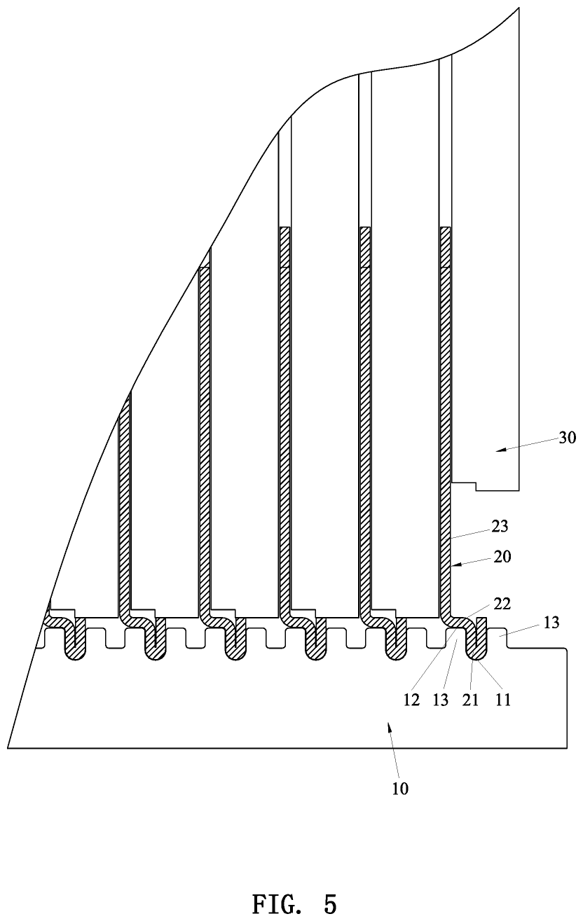

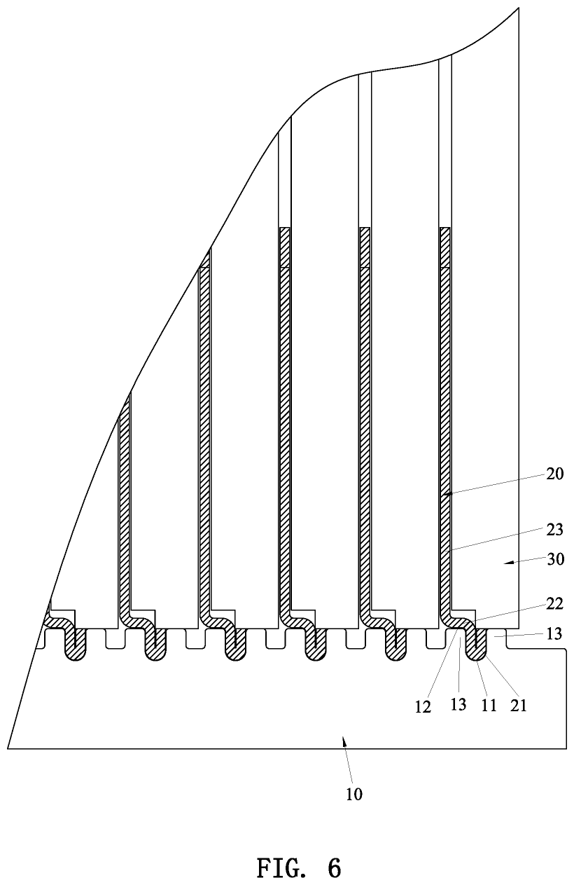

Through the base 10 and the heat sink fin 20 (as shown in FIG. 4), after the insertion portion 21 of the heat sink fin 20 is inserted in the groove 11 of the base 10 (as shown in FIG. 5), a press head 30 is aligned with the insertion portion 21 for pressing. The press head 30 covers the insertion portion 21. After pressing, the insertion portion 21 is pressed down in the groove 11 to be deformed, expanded and fitted in the groove 11 tightly (as shown in FIG. 6), such that the heat sink fin 20 is combined with the base 10, and the connecting portion 22 is in contact with the contact surface 22.

In use, the base 10 is in contact with a heat generating component, and the heat of the heat generating component is transferred to the base 10. Then, portion of the heat on the base 10 is transferred to the main body portion 23 through the insertion portion 21 and the connecting portion 22 sequentially for heat dissipation. The other portion of the heat on the base 10 is directly transferred to the connecting portion 22 through the contact surface 12, and then is transferred from the connecting portion 22 to the main body portion 23 for heat dissipation.

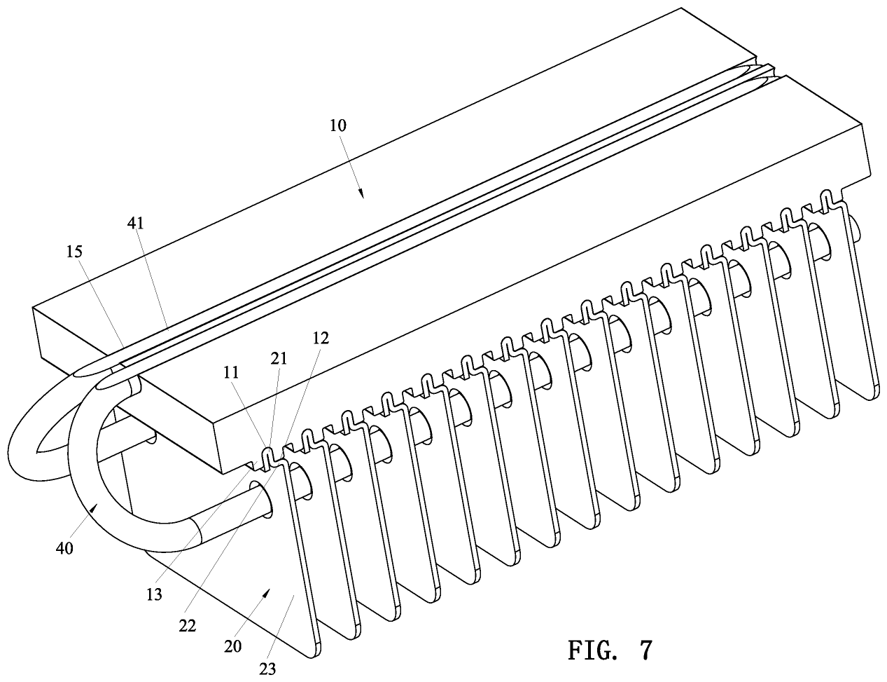

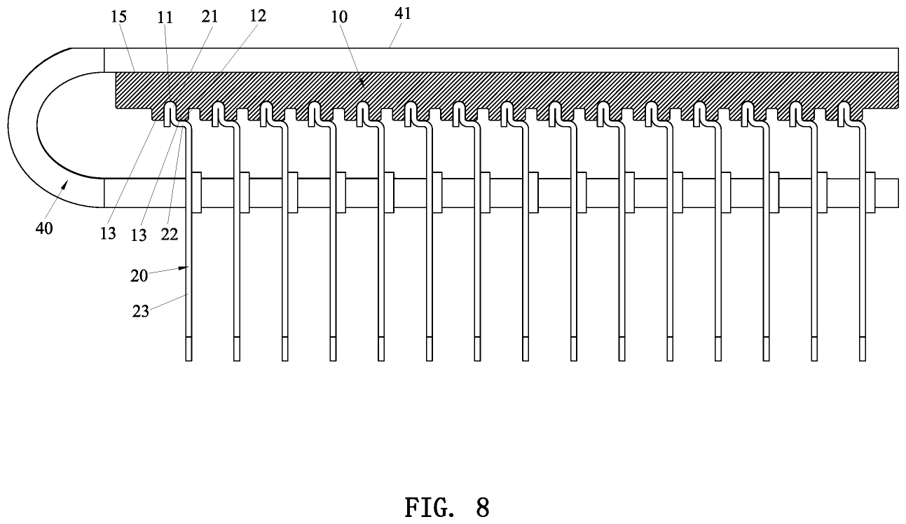

Referring to FIG. 7 and FIG. 8, a specific structure in accordance with a second embodiment of the present invention is shown. The second embodiment is substantially similar to the first embodiment with the exceptions described hereinafter.

In this embodiment, the underside of the base 10 is formed with at least one engaging groove 15 for attachment of a heat guide pipe 40. The heat guide pipe 40 has a flat bottom surface 41 that is exposed to the underside of the base 10. The heat guide pipe 40 is bent to pass through the main body portion 23 of the heat sink fin 20 in a tight-fit manner. By providing the heat guide pipe 40, the heat on the base 10 can be transferred to the main body portion 23 of the heat sink fin 20 through the heat guide pipe 40 to improve heat dissipation efficiency.

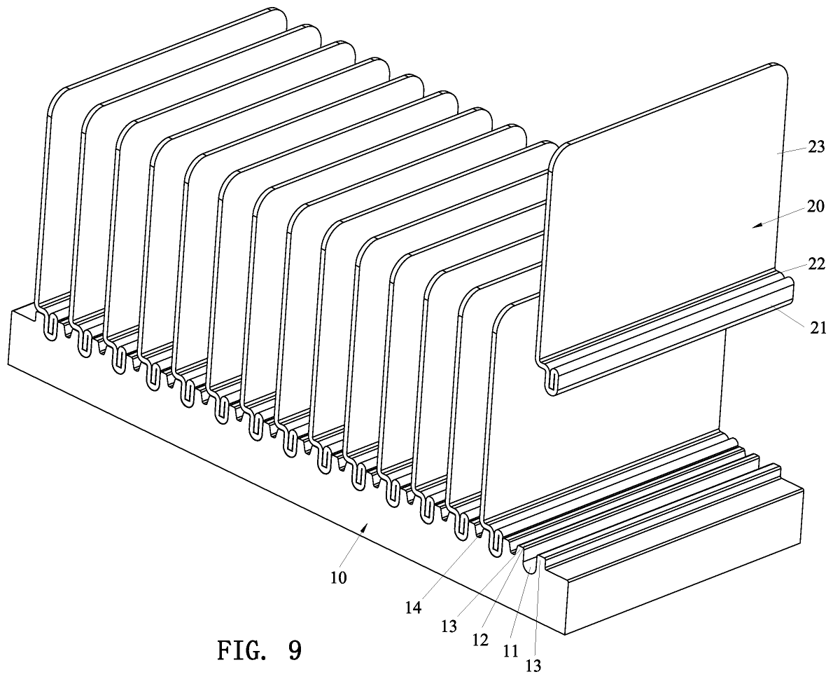

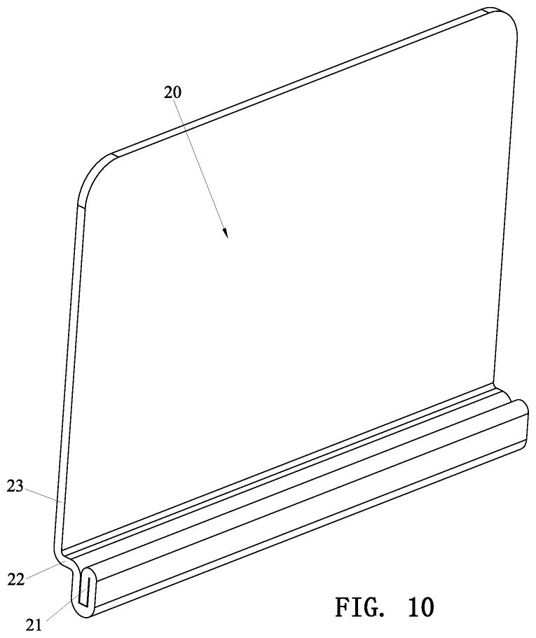

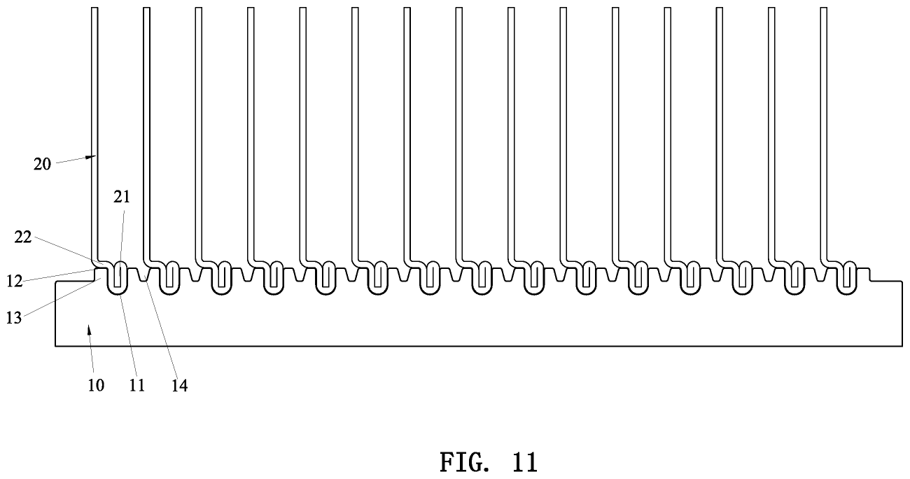

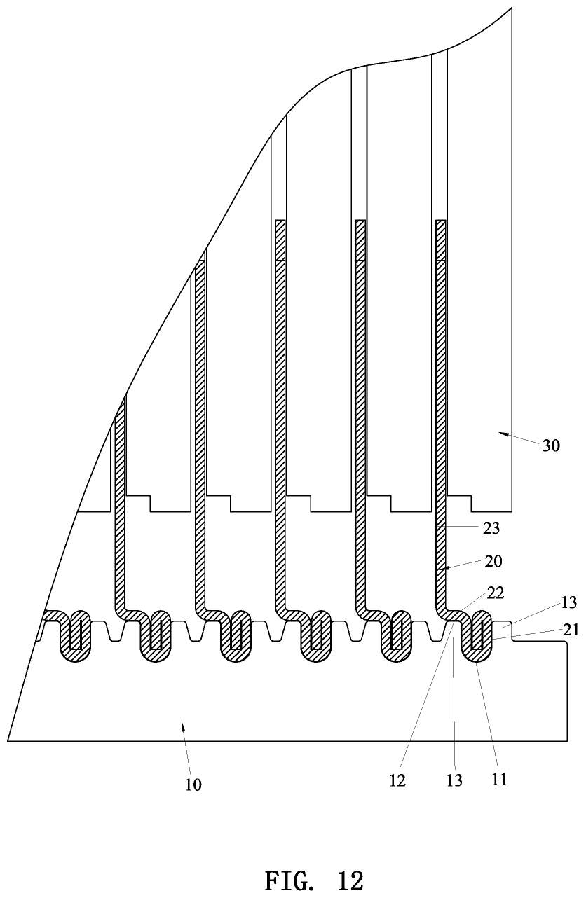

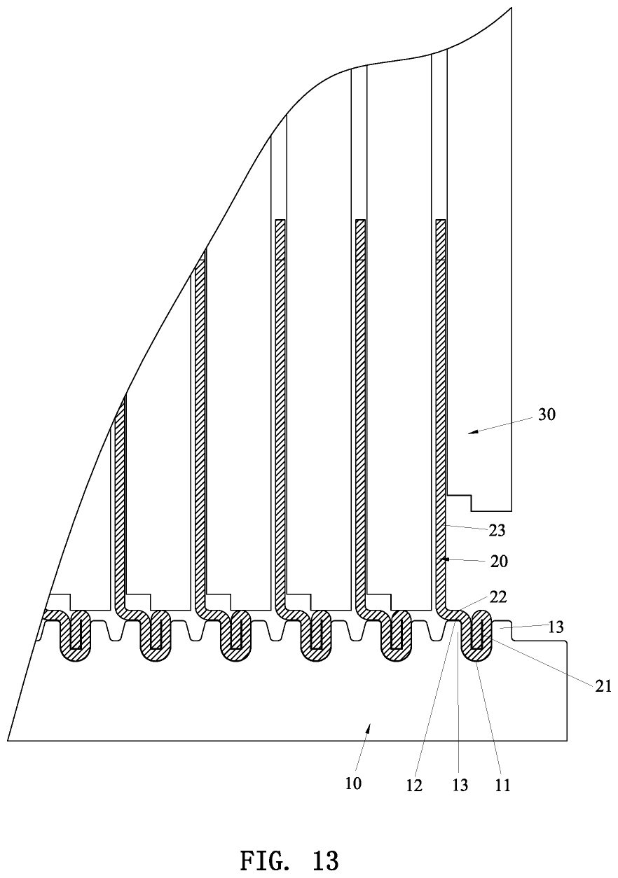

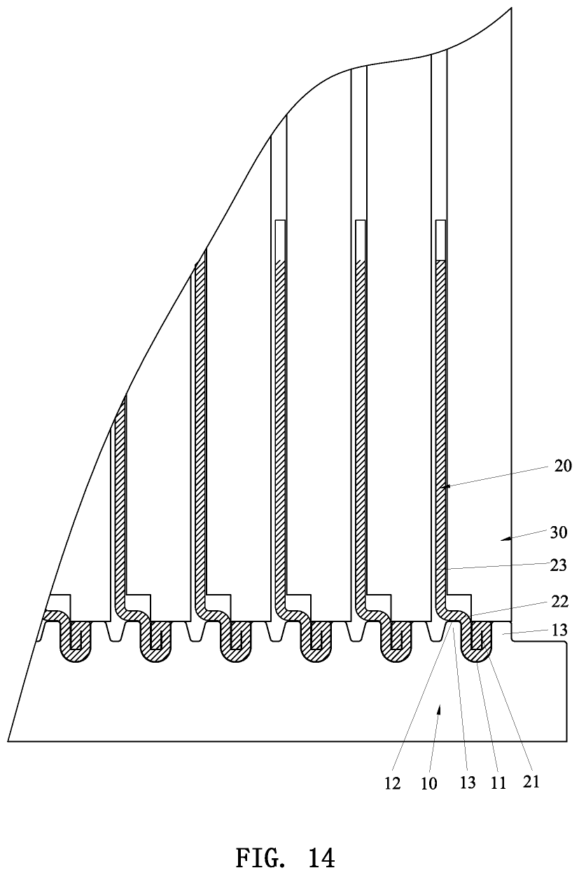

Referring to FIG. 9 through FIG. 14, a specific structure in accordance with a third embodiment of the present invention is shown. The third embodiment is substantially similar to the first embodiment with the exceptions described hereinafter.

In this embodiment, the insertion portion 21 is formed by folding at least twice to form a coil structure, so that the connection between the insertion portion 21 and the base 10 is more firm and reliable, and the contact area is larger, thereby improving heat dissipation efficiency.

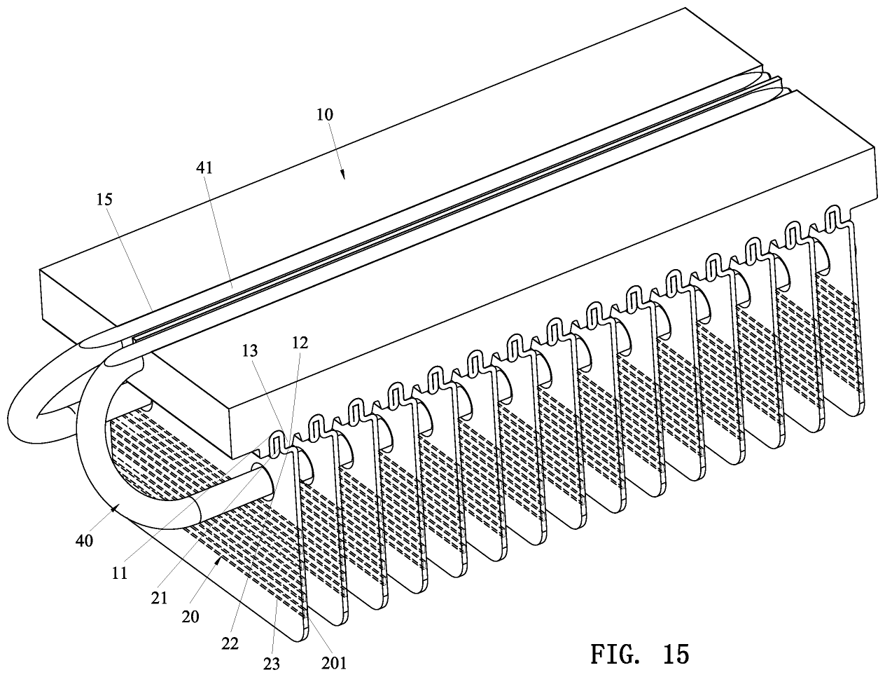

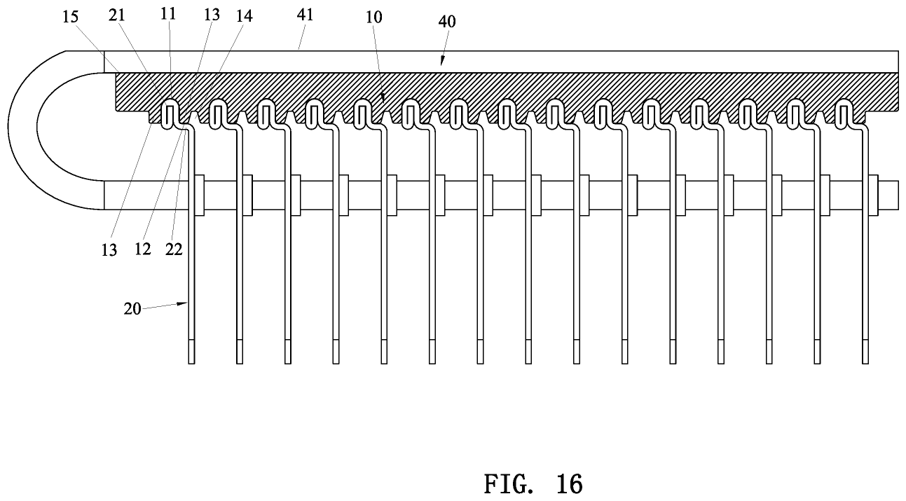

Referring to FIG. 15 and FIG. 16, a specific structure in accordance with a fourth embodiment of the present invention is shown. The fourth embodiment is substantially similar to the second embodiment with the exceptions described hereinafter.

In this embodiment, the insertion portion 21 is formed by folding at least twice to form a coil structure, so that the connection between the insertion portion 21 and the base 10 is more firm and reliable, and the contact area is larger, thereby improving heat dissipation efficiency. One end face of the main body portion 23 is formed with an accommodating groove 201 to accommodate a liquid coolant for improving the heat dissipation effect.

Although particular embodiments of the present invention have been described in detail for purposes of illustration, various modifications and enhancements may be made without departing from the spirit and scope of the present invention. Accordingly, the present invention is not to be limited except as by the appended claims

What is claimed is:

1. A heat sink having a press-riveting structure, comprising a base and a heat sink fin, a surface of the base being formed with a groove for attachment of the heat sink fin, at least one side of an opening of the groove having a contact surface); the heat sink fin including an insertion portion, a connecting portion and a main body portion that are connected together, the insertion portion being a folded structure embedded in the groove, the connecting portion extending toward one side relative to the insertion portion and being at least partially in contact with the contact surface; wherein after the insertion portion of the heat sink fin is inserted in the groove of the base, a press head is aligned with the insertion portion for pressing, the press head covers the insertion portion, after pressing, the insertion portion is pressed down in the groove to be deformed, expanded and fitted in the groove tightly, such that the heat sink fin is combined with the base, and the connecting portion is in contact with the contact surface.

2. The heat sink as claimed in claim 1, wherein a strip-shaped platform is formed at either side of the groove, and the contact surface is located on a top surface of the strip-shaped platform.

3. The heat sink as claimed in claim 1, wherein the contact surface is a level surface, and an underside of the connecting portion is parallel to and in full contact with the contact surface.

4. The heat sink as claimed in claim 1, wherein the insertion portion, the connecting portion and the main body portion are integrally formed and connected from bottom to top, the insertion portion and the main body portion extend vertically, and the connecting portion extends horizontally.

5. The heat sink as claimed in claim 1, wherein the groove is plural and arranged in parallel at intervals, the heat sink fin is plural, and the insertion portion of each heat sink fin is embedded and fixed in the corresponding groove.

6. The heat sink as claimed in claim 1, wherein the insertion portion is a U-shaped structure that is formed by folding one time.

7. The heat sink as claimed in claim 1, wherein the insertion portion is formed by folding at least twice to form a coil structure.

8. The heat sink as claimed in claim 1, wherein an underside of the base is formed with at least one engaging groove for attachment of a heat guide pipe, and the heat guide pipe has a flat bottom surface that is exposed to the underside of the base.

9. The heat sink as claimed in claim 8, wherein the heat guide pipe is bent to pass through the main body portion of the heat sink fin in a tight-fit manner.

10. The heat sink as claimed in claim 1, wherein one end face of the main body portion is formed with an accommodating groove for accommodating a liquid coolant.
